(19) United States
(12) Patent Application Publication
(10) Pub. No.: US 2024/0065067 A1
(43) Pub. Date: Feb. 22, 2024

(54) PIXEL STRUCTURE

(71) Applicants: HUIZHOU CHINA STAR OPTOELECTRONICS DISPLAY CO., LTD., Huizhou (CN); SHENZHEN CHINA STAR OPTOELECTRONICS SEMICONDUCTOR DISPLAY TECHNOLOGY CO., LTD., Shenzhen (CN)

(72) Inventor: Guojie WANG, Huizhou (CN)

(73) Assignees: HUIZHOU CHINA STAR OPTOELECTRONICS DISPLAY CO., LTD., Huizhou (CN); SHENZHEN CHINA STAR OPTOELECTRONICS SEMICONDUCTOR DISPLAY TECHNOLOGY CO., LTD., Shenzhen (CN)

(21) Appl. No.: 18/175,531

(22) Filed: Feb. 27, 2023

(30) Foreign Application Priority Data
Aug. 18, 2022 (CN) 202210990803.0

(51) Int. Cl. H10K 59/35; G09G 3/3208; G09G 3/20

(52) U.S. Cl. CPC H10K 59/353; G09G 3/3208; G09G 3/2003; H10K 59/352; G09G 2300/0452; G09G 2300/0465; G09G 2320/043

(57) ABSTRACT

An embodiment of the present application provides a pixel structure, including first sub-pixels, second sub-pixels, and blue sub-pixels. In a repeating unit, the first sub-pixel and the blue sub-pixel are arranged around the second sub-pixel, and the first sub-pixel and the blue sub-pixel are spaced apart, and spacing distances between one of the first sub-pixels and the blue sub-pixels adjacent thereto are unequal and include at least the first distance and the second distance. By making the spacing distances between one of the first sub-pixels and the blue sub-pixels adjacent thereto be unequal and the spacing distances including at least the first distance and the second distance, the displayed dark lines are reduced by a more scattered arrangement of the blue sub-pixels.

### CROSS-REFERENCE TO RELATED APPLICATION

This application claims priority to and the benefit of Chinese Patent Application No. 202210990803.0, filed on Aug. 18, 2022, the entire content of which is hereby incorporated by reference.

### TECHNICAL FIELD

The present application relates to a display technology field, and more particularly to a pixel structure.

### BACKGROUND

An Organic Light Emitting Diode (OLED) device has characteristics such as self-luminescence, wide viewing angle, high contrast, fast response speed, light weight and thin thickness and has become a main trend of display technology. A pixel arrangement structure for OLED is generally composed of a plurality of pixel, each of which includes a red sub-pixel, a green sub-pixel, and a blue sub-pixel, where the red sub-pixel, the green sub-pixel, and the blue sub-pixel are sequentially arranged in a circular manner to constitute a matrix. The pixel arrangement has an important influence on the OLED display technology. The blue sub-pixel has a dark brightness and a short life, and the brightness is decreased seriously with prolongation of the use time, so that dark lines are easily formed.

Therefore, there is a technical problem of displaying a plurality of dark lines in a conventional pixel structure.

### SUMMARY

An embodiment of the present application provides a pixel structure, which can alleviate the technical problem of displaying the plurality of dark lines in the conventional pixel structure.

An embodiment of the present application provides a pixel structure, including: first sub-pixels, second sub-pixels, and blue sub-pixels, wherein the first sub-pixels have a different emission color different from the second sub-pixels; in each of repeating units, the first sub-pixels and the blue sub-pixels are arranged around one of the second sub-pixels, the second sub-pixel is located in a region surrounded by the first sub-pixels and the blue sub-pixels, the first sub-pixels and the blue sub-pixels are disposed at intervals, and spacing distances between one of the first sub-pixels and the blue sub-pixels adjacent thereto are unequal.

Optionally, in some embodiments of the present application, the spacing distances include at least a first distance and a second distance, the ratio of the sum of the first distance and the second distance to the first distance is 1:0.618.

Optionally, in some embodiments of the present application, the first distance is 97.07 microns and the second distance is 60 microns.

Optionally, in some embodiments of the present application, the blue sub-pixels are disposed in a non-linear random arrangement, and the range of a randomness rate of the non-linear random arrangement is greater than 0 and less than or equal to 5%.

Optionally, in some embodiments of the present application, the number of the blue sub-pixels is greater than the number of the second sub-pixels.

Optionally, in some embodiments of the present application, a ratio of the number of the first sub-pixels:the number of the second sub-pixels:the number of the blue sub-pixels is 1:1:2.

Optionally, in some embodiments of the present application, an area of any of the blue sub-pixels is less than an area of any of the second sub-pixels.

Optionally, in some embodiments of the present application, a cross-sectional shape of each of the second sub-pixels is at least one of circular, rectangular, trapezoidal, or special shape.

Optionally, in some embodiments of the present application, the cross-sectional shape of each of the second sub-pixels is special shape, the shape of the second sub-pixel is complementary to the shape of the first sub-pixel adjacent thereto, and/or the shape of the second sub-pixel is complementary to the shape of the blue sub-pixel adjacent thereto.

Optionally, in some embodiments of the present application, the first sub-pixels and the second sub-pixels are arranged in an array.

The present application has a beneficial effect of reducing the display dark lines, by configuring that spacing distances between one of the first sub-pixels and the blue sub-pixels adjacent thereto are unequal, the spacing distances include at least the first distance and the second distance, and the blue sub-pixels are disposed in the non-linear random arrangement.

### BRIEF DESCRIPTION OF THE DRAWINGS

In order to more clearly illustrate the technical solutions in embodiments of the present disclosure, the accompanying drawings depicted in the description of the embodiments will be briefly described below. It will be apparent that the accompanying drawings in the following description are merely some embodiments of the present disclosure, and other drawings may be obtained from these drawings without creative effort by those skilled in the art.

FIG. 1 is a first schematic diagram of a pixel structure according to an embodiment of the present application;

FIG. 2 is an emulation diagram of dark lines of a pixel structure at different randomness rates according to an embodiment of the present application;

FIG. 3 is a second schematic diagram of a pixel structure according to an embodiment of the present application;

FIG. 4 is a third schematic diagram of a pixel structure according to an embodiment of the present application; and

FIG. 5 is a fourth schematic diagram of a pixel structure according to an embodiment of the present application.

Reference numerals:

| Reference signs: | Component names |
|---|---|
| 1 | pixel structure |
| 2 | repeating unit |
| 3 | minimum repeating unit |
| 10 | first sub-pixel |
| 20 | second sub-pixel |
| 30 | blue sub-pixel |
| 40 | first distance |
| 50 | second distance |

### EMBODIMENTS OF THE PRESENT DISCLOSURE

Technical solutions in embodiments of the present application will be clearly and completely described below in conjunction with drawings in the embodiments of the present application. Obviously, the described embodiments are only a part of embodiments of the present application, rather than all the embodiments. Based on the embodiments in the present application, all other embodiments obtained by those skilled in the art without creative work fall within the protection scope of the present application. In addition, it should be understood that the specific implementations described here are only used to illustrate and explain the present disclosure, and are not used to limit the present disclosure. In the present application, unless otherwise stated, directional words used such as “upper” and “lower” generally refer to the upper and lower directions of the device in actual use or working state, and specifically refer to the drawing directions in the drawings; and “inner” and “outer” refer to the outline of the device.

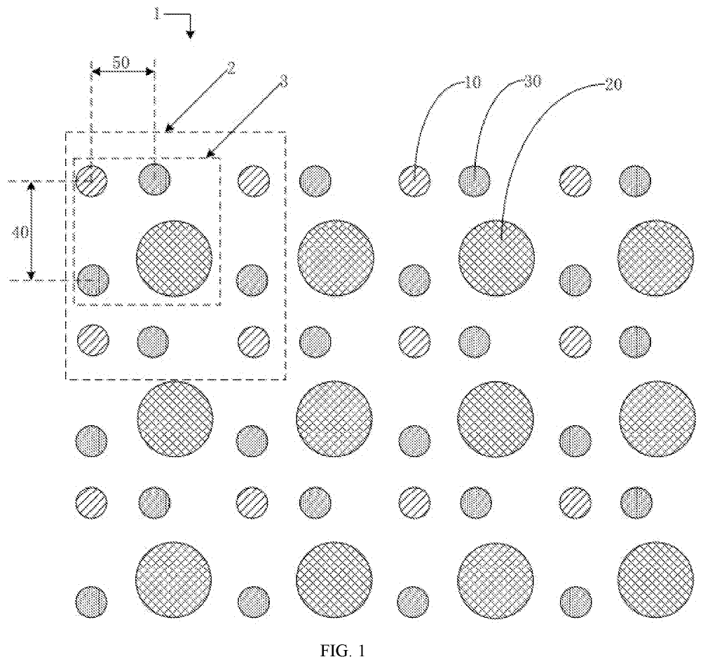

Referring to FIG. 1, a pixel structure 1 according to an embodiment of the present application includes first sub-pixels 10, second sub-pixels 20, and blue sub-pixels 30. In each of repeating units 2, the first sub-pixels 10 and the blue sub-pixels 30 are arranged around one of the second sub-pixels 20, the first sub-pixels 10 and the blue sub-pixels 30 are disposed at intervals, spacing distances between one of the first sub-pixels 10 and the blue sub-pixels 30 adjacent thereto are unequal, and the spacing distances include at least a first distance 40 and a second distance 50.

The second sub-pixel 20 may be centered within each of the repeating units 2.

In the embodiment, spacing distances between one of the first sub-pixels 10 and the blue sub-pixels 30 adjacent thereto are unequal, and the spacing distances include at least the first distance 40 and the second distance 50, so the display dark lines are reduced by a more scattered arrangement of the blue sub-pixels 30.

Technical solutions of the present application will be described now in conjunction with specific embodiments of the present application.

An example in which the blue sub-pixels 30 are disposed in a non-linear random arrangement is taken in the embodiment of the present application, and the non-linear random arrangement of the red sub-pixels or the green sub-pixels also falls within the protection scope of the present application.

In addition, a distance, a randomness rate, a shape, a selected material, and the like in the present application are described in terms of the best or preferred embodiments only, and other technical solutions that can perform similar or same effects are also within the scope of the present invention, which are not described repeatedly.

In an embodiment, the ratio of the sum of the first distance 40 and the second distance 50 to the first distance 40 is about 1:0.618.

It should be understood that the aesthetics of the pixel arrangement is improved by making the first distance 40 and the second distance 50 satisfy the golden division ratio, and thus the display effect can be improved further.

In the embodiment, by making the ratio of the sum of the first distance 40 and the second distance 50 to the first distance 40 be about 1:0.618, the arrangement of the blue sub-pixels 30 is designed with reference to the golden section ratio, thereby improving the display effect.

In an embodiment, the first distance 40 is 97.07 microns and the second distance 50 is 60 microns.

It should be noted that the above distance values are exemplified according to a mass-produced production line data, and other distance values that satisfy the ratio of the sum of the first distance 40 and the second distance 50 to the first distance 40 of about 1:0.618 fall within the scope of the present application.

In the present embodiment, the design in which the first distance 40 is 97.07 microns and the second distance 50 is 60 microns has been produced, which has a process and equipment matching to the design. By setting those values, the conventional equipment can be used to reduce the cost.

In an embodiment, the spacing distances between one of the first sub-pixels 10 and the blue sub-pixels 30 adjacent thereto include the first distance 40, the second distance 50, and a third distance.

Further, the spacing distances between one of the first sub-pixels 10 and the blue sub-pixels 30 adjacent thereto may include other unequal distance values, as long as the blue sub-pixels need to be scattered.

It should be noted that the distances between each of the blue sub-pixels 30 and one of the first sub-pixels 10 may have a plurality of values. The present application only describes a first distance 40 and a second distance 50 that are not equal to each other. Other distance values fall within the protection scope of the present application, which are not repeatedly described herein.

In an embodiment, the blue sub-pixels 30 are disposed in a non-linear random arrangement, and the range of randomness rate of the non-linear random arrangement is greater than 0 and less than or equal to 5%.

The non-linear random arrangement of the blue sub-pixels 30 refers to an irregularly scattered arrangement of the blue sub-pixels 30, where the arrangement rule is non-linear and random; and the greater the percentage value of the randomness rate is, the greater the irregularly scattered degree of the blue sub-pixels 30 is.

Further, the randomness rate of such an arrangement can be defined to further reduce dark lines, where the dark lines may be cross lines or fine lines.

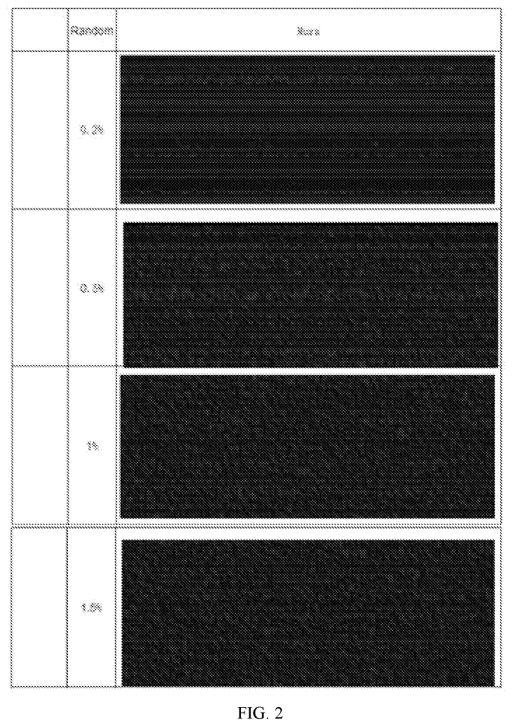

It should be understood that the randomness rate of 0.2%, 0.5%, 1%, and 1.5% are exemplified with reference to FIG. 2. When the randomness rate is 0.2%, there are still clearer dark lines although the dark lines are somewhat alleviated. The number of dark lines when the randomness rate is 0.5% is less than that when the randomness rate is 0.2%. The number of dark lines when the randomness rate is 1% is less than that when the randomness rate is 0.5%. The number of dark lines when the randomness rate is 1.5% is less than that when the randomness rate is 1%. Therefore, the number of the dark lines is decreased as the randomness rate is increased.

It should be understood that a technical effect of reducing the dark lines can be achieved by increasing the randomness rate, while a display effect can be further improved.

It should be noted that, although the number of the dark lines is decreased as the randomness rate is increased, the randomness rate cannot be excessively large. If the randomness rate is greater than 5%, there may be a conflict among other adjacent sub-pixels, which causes disadvantages such as a disadvantageous pixel arrangement or the presence of color crosstalk.

Further, if the randomness rate is capable of being greater than 5% for the pixel arrangement due to the progress of the process, the technical solution for further reducing the dark lines or improving the display effect is realized by increasing the randomness rate of the non-linear random arrangement of any sub-pixels without affecting the display, which also fall within the protection scope of the present application and are not described repeatedly herein.

In the present embodiment, the dark lines are further reduced by defining the randomness rate at which the blue sub-pixels 30 are disposed in the non-linear random arrangement.

In an embodiment, adjacent four blue sub-pixels 30 of each of the second sub-pixels 20 are located at four vertexes of a virtual isosceles trapezoid, respectively.

Each of the second sub-pixels 20 is provided with a plurality of first sub-pixels 10 and blue sub-pixels 30.

In an embodiment, the adjacent four blue sub-pixels 30 of each of the second sub-pixels 20 are located at four vertices of a virtual parallelogram, respectively.

The spacing distances between any of the first sub-pixels 10 and the blue sub-pixels 30 adjacent thereto include at least the first distance 40 and the second distance 50.

In an embodiment, each of the first sub-pixels 10 may be a red sub-pixel, and each of the second sub-pixels 20 may be a green sub-pixel.

In an embodiment, each of the first sub-pixels 10 may be a green sub-pixel, and each of the second sub-pixels 20 may be a red sub-pixel.

In an embodiment, the number of the blue sub-pixels 30 is greater than the number of the second sub-pixels 20.

The number of the blue sub-pixels 30 may be approximately twice the number of the second sub-pixels 20.

It should be understood that, by increasing the number of blue sub-pixels 30, the non-linear random arrangement of the blue sub-pixels 30 can be made more scattered, and the distribution density of the blue sub-pixels 30 can be increased, so that the display is finer and the particle sensation of the display is reduced.

It should be noted that, by increasing the number of blue sub-pixels 30, an area of single one of the blue sub-pixels 30 can also be reduced. Because the total area of the blue sub-pixels 30 in the pixel structure 1 is constant, it is possible to reduce the area of the single one of the blue sub-pixels 30 by increasing the number of the blue sub-pixels 30.

In the embodiment, by defining the number of the blue sub-pixels 30, the number of the blue sub-pixels 30 is larger than the number of the second sub-pixels 20, and the distribution density of the blue sub-pixels 30 is increased, so that the display is finer and the particle sensation of the display is reduced.

In an embodiment, the number of the blue sub-pixels 30 is greater than the number of the first sub-pixels 10.

In an embodiment, a ratio of the number of the first sub-pixels 10:the number of the second sub-pixels 20:the number of the blue sub-pixels 30 is 1:1:2.

Referring to FIG. 1, in a minimum repeating unit 3, the minimum repeating unit 3 includes one first sub-pixel 10, one second sub-pixel 20, and two blue sub-pixels 30, where the distances between the first sub-pixel 10 and either of the blue sub-pixel adjacent thereto are not equal, namely, a first distance 40 and a second distance 50, respectively.

In an embodiment, an area of any of the blue sub-pixels 30 is less than an area of any of the second sub-pixels 20.

The second sub-pixel 20 may be a green sub-pixel, and an area of the green sub-pixel may be twice that of the blue sub-pixel 30.

It should be understood that each of the blue sub-pixels 30 has a dark brightness and a short lifetime, and it is easy for the blue sub-pixel 30 to fail. By reducing the area of the single blue sub-pixel 30, the size of the dark line generated after the failure of the single blue sub-pixel 30 can be reduced, so that the blue sub-pixel 30 is prevented from being noticeable due to its larger area after the failure.

It should be understood that, in the prior art, the area of the blue sub-pixel 30 is generally larger and the area of the second sub-pixel 20 is smaller. The present application may replace the area of the blue sub-pixel 30 and the area of the second sub-pixel 20 in the prior art.

In the present embodiment, by setting the area of the blue sub-pixel 30 to be smaller than that of the second sub-pixel 20, the single blue sub-pixel 30 does not form a larger dark line after being disabled, thereby reducing the influence of the failure of the blue sub-pixel 30 on the display effect and reducing the displayed dark lines.

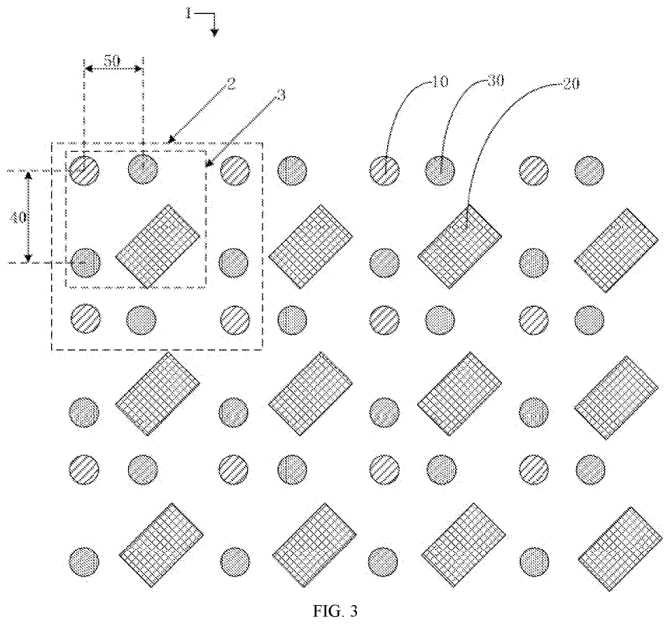

In an embodiment, referring to FIG. 3, a cross-sectional shape of each of the second sub-pixels 20 may be at least one of circular, rectangular, trapezoidal, or special shape.

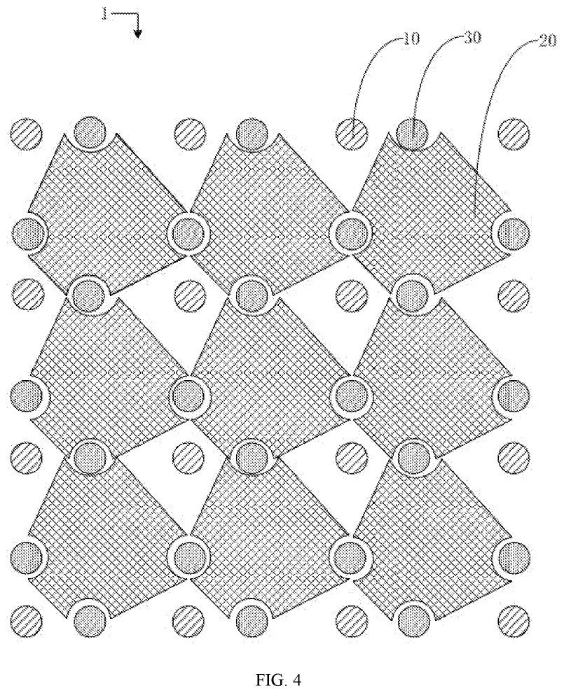

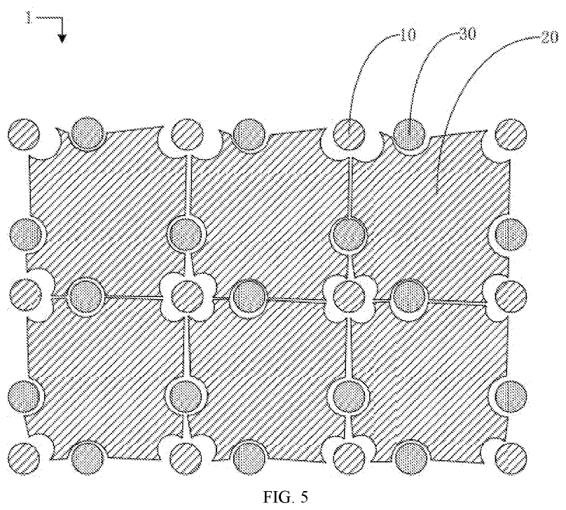

In an embodiment, referring to FIGS. 4 and 5, each of the second sub-pixels 20 is special shape, the shape of each of the second sub-pixels 20 is complementary to that of the first sub-pixel 10 adjacent thereto, and/or the shape of each of the second sub-pixels 20 is complementary to that of the blue sub-pixel 30 adjacent thereto.

Referring to FIG. 4, the cross-sectional shapes of the second sub-pixels 20 are complementary to those of the blue sub-pixels 30, so that the area of the single second sub-pixel 20 can be increased.

Referring to FIG. 5, the cross-sectional shapes of the second sub-pixels 20 are complementary to those of the blue sub-pixels 30 and the first sub-pixels 10, so that the area of the single second sub-pixel 20 can be further increased.

It should be understood that, by increasing the area of each of the second sub-pixels 20, more space may be reserved to set other sub-pixels, which may be the blue sub-pixels 30, the first sub-pixels 10, and the like.

It should be understood that, by setting the second sub-pixels 20 to be special shape and complementary to the first sub-pixels 10 and the blue sub-pixels 30 adjacent thereto, the area of the single second sub-pixel 20 can be increased, thereby reducing the number of the second sub-pixels 20. Moreover, space is saved to set more blue sub-pixels 30, thereby further increasing an arrangement density and the number of the blue sub-pixels 30.

In the embodiment, by setting the second sub-pixel 20 to be special shape, more space is reserved for setting other sub-pixels, thereby increasing an arrangement density of the sub-pixels per unit area and increasing the display brightness.

In an embodiment, the first sub-pixel 10 has the same cross-sectional shape as the blue sub-pixel 30.

Each of the first sub-pixels 10 and the blue sub-pixels 30 may have a circular cross-sectional shape.

Further, all of the first sub-pixels 10 and the blue sub-pixel 30s have a diameter of 30 microns.

Further, the first sub-pixels 10 may have the same size as the blue sub-pixels 30.

In the present embodiment, the first sub-pixel 10 and the blue sub-pixel 30 are designed in the same shape and size, so that the first sub-pixel 10 and the blue sub-pixel 30 share the same photomask in term of function, thereby reducing the cost.

In an embodiment, the first sub-pixels 10 and the second sub-pixels 20 are arranged in an array.

Another embodiment of the present application further provides a display panel, a display module, and a display apparatus. All of the display panel, the display module, and the display apparatus include the foregoing pixel structure, which is not repeatedly described herein.

The pixel structure provided in the embodiments includes the first sub-pixels, the second sub-pixels, and the blue sub-pixels. The first sub-pixels and the blue sub-pixels are arranged around the second sub-pixel in each of the repeating units, and the first sub-pixel and the blue sub-pixel are spaced apart, and the spacing distances between one of the first sub-pixels and the blue sub-pixels adjacent thereto are unequal, where the spacing distances include at least the first distance and the second distance. By making the spacing distances between one of the first sub-pixels and the blue sub-pixels adjacent thereto be unequal and the spacing distances including at least the first distance and the second distance, the displayed dark lines are reduced by a more scattered arrangement of the blue sub-pixels.

In the foregoing embodiments, descriptions of the embodiments are emphasized. Any portion that is not described in detail in any embodiment may refer to related description in another embodiment.

The pixel structure provided in the embodiments of the present application are described in detail above. Embodiments are used herein to describe a principle and an implementation of the present application. The description of the foregoing embodiments is merely used to help understand a method and a core idea of the present application. In addition, a person skilled in the art may make changes in a specific implementation manner and an application scope according to an idea of the present application. In conclusion, content of this specification should not be construed as a limitation on the present application.

What is claimed is:

1. A pixel structure, comprising:
first sub-pixels, second sub-pixels, and blue sub-pixels, wherein the first sub-pixels have a different emission color different from the second sub-pixels; in each of repeating units, the first sub-pixels and the blue sub-pixels are arranged around one of the second sub-pixels, the second sub-pixel is located in a region surrounded by the first sub-pixels and the blue sub-pixels, the first sub-pixels and the blue sub-pixels are disposed at intervals, and spacing distances between one of the first sub-pixels and the blue sub-pixels adjacent thereto are unequal.

2. The pixel structure of claim 1, wherein the spacing distances include at least a first distance and a second distance, the ratio of the sum of the first distance and the second distance to the first distance is 1:0.618.

3. The pixel structure of claim 2, wherein the first distance is 97.07 microns and the second distance is 60 microns.

4. The pixel structure of claim 2, wherein the blue sub-pixels are disposed in a non-linear random arrangement, and the range of a randomness rate of the non-linear random arrangement is greater than 0 and less than or equal to 5%.

5. The pixel structure of claim 2, wherein the number of the blue sub-pixels is greater than the number of the second sub-pixels.

6. The pixel structure of claim 5, wherein a ratio of the number of the first sub-pixels:the number of the second sub-pixels:the number of the blue sub-pixels is 1:1:2.

7. The pixel structure of claim 2, wherein an area of any of the blue sub-pixels is less than an area of any of the second sub-pixels.

8. The pixel structure of claim 2, wherein a cross-sectional shape of each of the second sub-pixels is at least one of circular, rectangular, trapezoidal, or special-shaped.

9. The pixel structure of claim 8, wherein the cross-sectional shape of each of the second sub-pixels is special shape, the shape of the second sub-pixel is complementary to the shape of the first sub-pixel adjacent thereto, and/or the shape of the second sub-pixel is complementary to the shape of the blue sub-pixel adjacent thereto.

10. The pixel structure of claim 2, wherein the first sub-pixels and the second sub-pixels are arranged in an array.

11. The pixel structure of claim 1, wherein the second sub-pixel is centered within each of the repeating units.

12. The pixel structure of claim 1, wherein the spacing distances include a first distance, a second distance, and a third distance.

13. The pixel structure of claim 1, wherein adjacent four blue sub-pixels of each of the second sub-pixels are located at four vertexes of a virtual isosceles trapezoid, respectively.

14. The pixel structure of claim 1, wherein each of the second sub-pixels is provided with a plurality of first sub-pixels and blue sub-pixels.

15. The pixel structure of claim 1, wherein adjacent four blue sub-pixels of each of the second sub-pixels are located at four vertices of a virtual parallelogram, respectively.

16. The pixel structure of claim 2, wherein each of the first sub-pixels is a red sub-pixel and each of the second sub-pixels is a green sub-pixel; or each of the first sub-pixels is a green sub-pixel and each of the second sub-pixels is a red sub-pixel.

17. The pixel structure of claim 1, wherein each of the first sub-pixels has the same cross-sectional shape as each of the blue sub-pixels.

18. The pixel structure of claim 1, wherein each of the first sub-pixels has the same size as each of the blue sub-pixels.

19. A display panel, comprising a pixel structure, wherein the pixel structure comprises:
first sub-pixels, second sub-pixels, and blue sub-pixels, wherein the first sub-pixels and the second sub-pixels have a different emission color different from the second sub-pixels; in each of repeating units, the first sub-pixels and the blue sub-pixels are arranged around one of the second sub-pixels, the second sub-pixel is located in a region surrounded by the first sub-pixels and the blue sub-pixels, the first sub-pixels and the blue sub-pixels are disposed at intervals, and spacing distances between one of the first sub-pixels and the blue sub-pixels adjacent thereto are unequal.

20. A display apparatus, comprising a pixel structure, wherein the pixel structure comprises:
first sub-pixels, second sub-pixels, and blue sub-pixels, wherein the first sub-pixels and the second sub-pixels have a different emission color different from the second sub-pixels; in each of repeating units, the first sub-pixels and the blue sub-pixels are arranged around one of the second sub-pixels, the second sub-pixel is located in a region surrounded by the first sub-pixels and the blue sub-pixels, the first sub-pixels and the blue sub-pixels are disposed at intervals, and spacing distances between one of the first sub-pixels and the blue sub-pixels adjacent thereto are unequal.
